(19) United States
(12) Patent Application Publication
(10) Pub. No.: US 2016/0254485 A1
(43) Pub. Date: Sep. 1, 2016

(54) METHOD FOR PACKAGING OLED DEVICE, OLED DISPLAY PANEL AND OLED DISPLAY APPARATUS

(71) Applicant: BOE TECHNOLOGY GROUP CO., LTD., Beijing (JP)

(72) Inventor: Wenfeng Song, Beijing (CN)

(21) Appl. No.: 14/770,247

(22) PCT Filed: Sep. 23, 2014
(86) PCT No.: PCT/CN2014/087199

§ 371 Date: Aug. 25, 2015

(30) Foreign Application Priority Data
Jun. 27, 2014 (CN) 201410301791.1

(51) Int. Cl. H01L 51/52; H01L 51/00; H01L 51/56

(52) U.S. Cl. CPC H01L 51/5246; H01L 51/5237; H01L 51/56; H01L 51/0021; H01L 51/0024

(57) ABSTRACT

Embodiments of the disclosure provide an OLED display panel, which comprises: a first substrate; a second substrate arranged opposite to the first substrate; and a thermally conductive layer, a first packaging adhesive, a second packaging adhesive and an OLED device between the first substrate and the second substrate, wherein the first packaging adhesive is arranged between the first substrate and the second substrate and encloses a sealed space with the first substrate and the second substrate; the thermally conductive layer is formed within the space enclosed by the first packaging adhesive and includes at least two regions having different conductivities, wherein at least an edge region of the thermally conductive layer has a higher conductivity than a central region of the thermally conductive layer; the second packaging adhesive fills the space enclosed by the first substrate, the second substrate and the first packaging adhesive, and is in contact with a surface of the thermally conductive layer. The disclosure further provides an OLED display apparatus and a method for packaging an OLED device.

### TECHNICAL FIELD

The disclosure generally relates to the technical field of displaying, and more particularly, to a method for packaging an OLED device, an OLED display panel and an OLED display apparatus.

### BACKGROUND

Due to its advantages such as thinness, light weight, wide viewing angle, active light emitting, continuously adjustable colour of emitted light, low cost, quick response, low power consumption, low driving voltage, wide operating temperature range, simple manufacturing process, efficient light emitting and flexible displaying, etc., organic light-emitting diode (OLED) display panel has been listed as a highly promising next-generation display technology.

Studies show that substances such as moisture and oxygen in the air greatly affect the lifetime of the OLED devices in the OLED display panel. This is because when the OLED device operates electrons needs to be injected from its cathode. This requires the cathode work function to be as low as possible. However, the cathode is typically made of metal such as aluminum, magnesium, calcium, etc. which is active chemically and is prone to react with moisture and oxygen permeating the OLED device. In addition, moisture and oxygen also react chemically with hole transport and electron transport layers of the OLED device, which causes malfunction of the OLED device. Therefore, if the OLED device is effectively packaged so that functional layers of the OLED device are fully insulated from substances such as moisture and oxygen in the air, the lifetime of the OLED device and hence the OLED panel can be greatly prolonged.

Nowadays, approaches for packaging an OLED device mainly include, among others, dry sheet pasting and covering+UV adhesive coating, surface packaging, glass glue packaging, film packaging, etc. Packaging using a dam and a filler belongs to surface packaging. The dam can effectively prevent moisture and oxygen from invading while the filler filling the space between a cover plate and a substrate enables the OLED device to effectively cope with external pressures. This packaging method is flexible and convenient, and can be easily adapted to suit devices of different sizes. Meanwhile, because the filler has a high transparency, this packaging method can be used for packaging not only bottom-emitting devices but also top-emitting devices. Therefore, it is one of today's highly promising packaging methods.

However, in pressing the substrate to the cover plate, the filler contacts the incompletely cured dam as the filler spreads, so that the dam is impacted and deformed. Accordingly, a certain degree of flaw is present in the interface where the dam contacts the filler, thereby affecting the moisture and oxygen barrier performance of the dam and unfavorably resulting in damage to the OLED device and shortened lifetime of the device.

### SUMMARY

In view of the foregoing, the present disclosure provides a method packaging an OLED device, an OLED display panel and an OLED display apparatus.

According to an aspect of the disclosure, there is provided an OLED display panel, which comprises a first substrate; a second substrate arranged opposite to the first substrate; and a thermally conductive layer, a first packaging adhesive, a second packaging adhesive and an OLED device between the first substrate and the second substrate, wherein

the first packaging adhesive is arranged between the first substrate and the second substrate and encloses a sealed space with the first substrate and the second substrate,

the thermally conductive layer is formed within the space enclosed by the first packaging adhesive and includes at least two regions having different conductivities, wherein at least an edge region of the thermally conductive layer has a higher conductivity than a central region of the thermally conductive layer,

the second packaging adhesive fills the space enclosed by the first substrate, the second substrate and the first packaging adhesive, and is in contact with a surface of the thermally conductive layer.

In a possible implementation, the thermally conductive layer includes at least two thermally conductive regions from its edge to its center, and conductivities of the thermally conductive regions decrease monotonically from the edge to the center.

In a possible implementation, a material of a thermally conductive region at the edge of the thermally conductive layer has a higher conductivity than a material of a thermally conductive region at the center of the thermally conducive layer, or

the thermally conductive region at the edge of the thermally conductive layer and the thermally conductive region at the center of the thermally conductive layer are made of the same basic material, wherein a material layer having a lower conductivity is formed at the thermally conductive region at the center, or

the thermally conductive region at the edge of the thermally conductive layer and the thermally conductive region at the center of the thermally conductive layer are made of the same basic material, wherein the thermally conductive region at the edge is doped with a thermally conductive material, or

the thermally conductive region at the edge of the thermally conductive layer and the thermally conductive region at the center of the thermally conductive layer are made of the same basic material and are both doped with a thermally conductive material, wherein the thermally conductive material (8) with which the thermally conductive region at the edge is doped has a higher concentration than the thermally conductive material with which the thermally conductive region at the center is doped, or

the thermally conductive region at the edge of the thermally conductive layer and the thermally conductive region at the center of the thermally conductive layer are made of the same basic material, wherein the thermally conductive region at the center is doped with a thermally insulting material, or

the thermally conductive region at the edge of the thermally conductive layer and the thermally conductive region at the center of the thermally conductive layer are made of the same basic material, wherein the thermally insulating material with which the thermally conductive region at the center is doped has a higher concentration than the thermally insulating material with which the thermally conductive region at the edge is doped.

In a possible implementation, the material of the thermally conductive region at the edge is selected from a metal, a metal oxide, an inorganic/organic having a high conductivity, or a thermally conductive polymer, and the material of the thermally conductive region at the center is an inorganic having a low conductivity; or the basic material is selected from a metal, a metal oxide, an inorganic/organic having a high conductivity, or a thermally conductive polymer, and the material having a lower conductivity is an inorganic having a low conductivity; or the basic material is selected from a metal, a metal oxide, an inorganic/organic having a high conductivity, or a thermally conductive polymer, and the thermally conductive material is carbon nanotubes or a metal.

In a possible implementation, the thermally conductive layer is rectangular.

In a possible implementation, the OLED display panel further comprises: a passivation layer covering the OLED device and connected to the second substrate in a sealed manner.

According to another aspect of the disclosure, there is provided an OLED display apparatus, comprising an OLED display panel described above.

According to a further aspect of the disclosure, there is provided a method for packaging an OLED device. The method comprises:

forming a thermally conductive layer, which includes at least two regions having different conductivities, on a surface of a first substrate or a second substrate, wherein at least an edge region of the thermally conductive layer has a higher conductivity than a central region of the thermally conductive layer;

forming a first packaging adhesive on a peripheral edge of the first substrate or the second substrate so that the first packaging adhesive encloses a sealed space with the first substrate and the second substrate, the thermally conductive layer being arranged within the space enclosed by the first packaging adhesive;

forming a second packaging adhesive on the first substrate or the second substrate;

connecting the second substrate where the OLED device is formed and the first substrate via the first packaging adhesive, wherein the first packaging adhesive encloses the sealed space with the first substrate and the second substrate; and

curing the first packaging adhesive and the second packaging adhesive respectively, so that the second packaging adhesive fills up the sealed space.

In a possible implementation, at least two thermally conductive regions are formed on the surface of the first substrate or the second substrate from an edge to a center of the first substrate or the second substrate, and conductivities of the thermally conductive regions decrease monotonically from the edge to the center.

In a possible implementation, the at least two thermally conductive regions are formed on the surface of the first substrate or the second substrate from the edge to the center of the first substrate or the second substrate by:

forming a first thermally conductive layer at the edge of the first substrate or the second substrate and forming a second thermally conductive layer at the center of the first substrate or the second substrate, wherein a material of the first thermally conductive layer has a higher conductivity than a material of the second thermally conductive layer, or

forming a first thermally conductive layer on the surface of the first substrate or the second substrate and forming a second thermally conductive layer at the center of the first thermally conductive layer, wherein a material of the first thermally conductive layer has a higher conductivity than a material of the second thermally conductive layer, or

forming a first thermally conductive layer on the surface of the first substrate or the second substrate and doping the first thermally conductive layer at its edge with a thermally conductive material;

forming a first thermally conductive layer on the surface of the first substrate or the second substrate and doping the first thermally conductive layer with a thermally conductive material, wherein the thermally conductive material in a thermally conductive region at the edge has a higher concentration than in a thermally conductive region at the center, or

forming a first thermally conductive layer on the surface of the first substrate or the second substrate and doping the first thermally conductive layer at its center with a thermally insulating material, or

forming a first thermally conductive layer on the surface of the first substrate or the second substrate and doping the first thermally conductive layer with a thermally conductive material, wherein the thermally insulating material in a thermally conductive region at the center has a higher concentration than in a thermally conductive region at the edge.

In a possible implementation, a material of the first packaging adhesive includes a liquid adhesive having a high viscosity and a high impermeability, and a material of the second packaging adhesive includes a hydrophobic liquid adhesive having a low viscosity and a high fluidity.

In a possible implementation, an active ingredient of the materials of both the first packaging adhesive and the second packaging adhesive includes epoxy resin, and the epoxy resin accounts for a lower percentage in the material of the second packaging adhesive than in the material of the first packaging adhesive.

In a possible implementation, the packaging method further comprises: forming, on the OLED device, a passivation layer connected to the second substrate in a sealed manner, before connecting the second substrate where the OLED device is formed and the first substrate via the first packaging adhesive.

According to the disclosure, a thermally conductive layer which includes at least two regions having different conductivities is arranged, at least the edge region of the thermally conductive layer has a higher conductivity than the central region of the thermally conductive layer, and the thermally conductive layer is in contact with the second packaging adhesive. As such, a temperature difference is created between different positions on the second packaging adhesive and thus the speed at which the second packaging adhesive spreads in all directions from the center is controlled, thereby enabling a flawless contact between the second packaging adhesive and the incompletely cured first packaging adhesive and preventing the second packaging adhesive from causing damage to the first packaging adhesive. Additionally, the first packaging adhesive, the second package adhesive and the passivation layer can all block moisture and oxygen. Meanwhile, the passivation layer can also prevent the second packaging adhesive from directly contacting the OLED device and thus affecting the performance characteristics of the OLED device. Therefore, the technical solutions of the disclosure can not only ensure moisture and oxygen barrier performance of the first packaging adhesive but also fully insulate the functional layers of the OLED device from substances in the atmosphere such as moisture, oxygen, etc., thereby significantly prolonging the lifetime of the OLED device and the OLED display panel.

### BRIEF DESCRIPTION OF THE DRAWINGS

FIG. 1 is a schematic diagram illustrating a cross-sectional structure of an OLED display panel according to an embodiment of the disclosure;

FIG. 2 is a schematic diagram illustrating a cross-sectional structure of an OLED display panel according to another embodiment of the disclosure;

FIG. 3 is a diagram illustrating a cross-sectional structure of an OLED display panel according to a further embodiment of the disclosure;

FIGS. 4a-4f are diagrams illustrating a process of packaging an OLED device according to an embodiment of the disclosure.

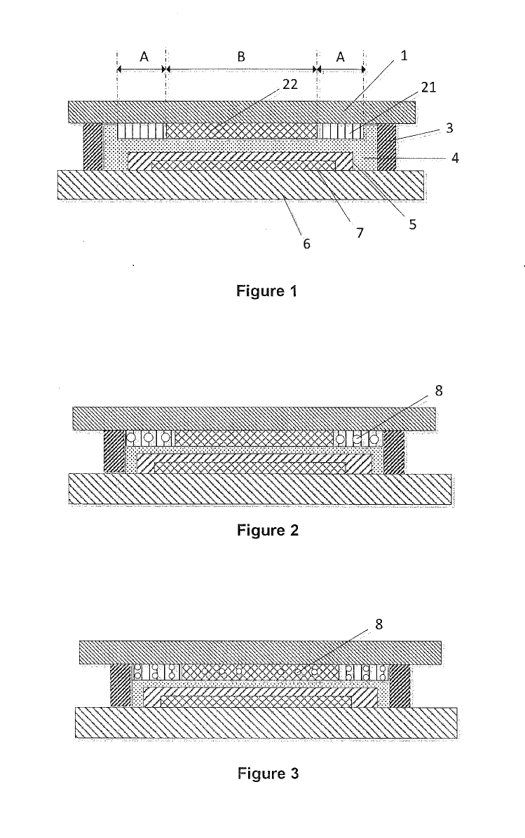

### DETAILED DESCRIPTION OF EMBODIMENTS

For the object, technical solutions and advantages of the disclosure to be more clear and apparent, the disclosure will further elucidated in conjunction with detailed embodiments and with reference to accompanying drawings in the following.

According to an aspect of the disclosure, there is provided an OLED display panel. The OLED display panel comprises: a first substrate 1 and a second substrate 2 arranged opposite to each other; and a thermally conductive layer 2, a first packaging adhesive 1, a second adhesive 4 and an OLED 7 between the first substrate 1 and the second substrate 7. The first packaging adhesive 3 is arranged between the first substrate 1 and the second substrate 6, and forms a sealed space with the first substrate 1 and the second substrate 6.

In an embodiment of the disclosure, the first packaging adhesive 3 is arranged on a peripheral edge of the first substrate 1. Of course, the first packaging adhesive 3 may also be arranged on a peripheral edge of the second substrate 6. The disclosure by no means limit the specific position where the first packaging adhesive 3 is formed but only requires that the first packaging adhesive 3 is between the first substrate 1 and the second substrate 6, encloses a sealed space with the first substrate 1 and the second substrate 6 and surrounds the thermally conductive layer 2.

The thermally conductive layer 2 is formed within the space enclosed by the first packaging adhesive 3 and includes at least two regions having different conductivities, wherein at least an edge region of the thermally conductive layer 2 has a higher conductivity than a central region of the thermally conductive layer 2. Preferably, the thermally conductive layer 2 includes at least two thermally conductive regions from its edge to its center, and conductivities of the thermally conductive regions decrease monotonically from the edge to the center.

In an embodiment of the disclosure, the thermally conductive layer 2 includes a first thermally conductive region 21 at the edge and a second thermally conductive region 2 at the center. The first thermally conductive region 21 has a higher conductivity than the second thermally conductive region 22.

It can be envisaged that there are many other manners for arranging the thermally conductive regions in the thermally conductive layer 2. For example, the thermally conductive regions may be arranged in strips, and the thermally conductive region at the edge of the thermally conductive layer 2 has higher conductivities than the thermally conductive region at the center of the thermally conductive layer 2. As another example, the thermally conductive layer 2 may include multiple thermally conductive regions, each of which has a regular or irregular shape. The thermally conductive regions are arranged according to a certain rule to constitute the thermally conductive layer 2. Each thermally conductive region at the edge of the thermally conductive layer 2 has a higher conductivity than the thermally conductive regions at the center of the thermally conducive layer 2. The conductivities of the thermally conductive regions at the edge may be the same, different or locally the same. The conductivities of the thermally conductive regions at the center may be the same, different, or locally the same.

The thermally conductive layer 2 typically has a shape of rectangle, such as an oblong or a square.

The disclosure by no means limit the specific arrangement of the thermally conductive regions in the thermally conductive layer 2 but only requires that the thermally conductive layer 2 includes at least two thermally conductive regions and conductivities of the at least two thermally conductive regions decrease monotonically from the edge to the center of the thermally conductive layer 2. Also, the disclosure by no means limits the shape of the thermally conductive layer 2, and any suitable shape that can be formed within the space enclosed by the first packaging adhesive 3 falls within the protection scope of the disclosure.

The OLED device may be arranged on one side of the second substrate 6 which faces the first substrate 1.

The second packaging adhesive 4 fills the sealed space enclosed by the first substrate 1, the second substrate 6 and the first packaging adhesive 3, and is in contact with the surface of the thermally conductive layer 2.

As described above, the thermally conductive layer 2 includes at least two regions having different conductivities. In the following, description will be given by taking an example where the thermally conductive layer 2 includes two regions having different conductivities. Those skilled in the art shall appreciate that details for the case where the number of regions having different conductivities is more than two can be deduced from the case where there are two regions having different conductivities. No repetition will be made in the following. As for the case where the thermally conductive layer 2 includes two regions having different conductivities which are respectively located at the center and the edge and the conductivity of the first thermally conductive region 21 at the edge is higher than the conductivity of the second thermally conductive region 22 at the center, such a design is made for enabling the thermally conductive layer 2 to exhibit different conductivities when packaging a prepared panel, so that there is a temporal temperature difference between different thermally conductive regions. That is, the thermally conductive layer 2 has a higher temperature at the edge than at the center, and the second packaging adhesive 4 in contact with the surface of the thermally conductive layer 2 also exhibits different temperatures at positions corresponding to those on the thermally conductive layer 2. Therefore, when the second packaging adhesive 4 quickly spreads from the center to the edge and reaches the edge where the temperature is high, the second packaging adhesive in contact with the thermally conductive layer 2 will have a higher curing rate at the edge than at the center. The second packaging adhesive 4 at the edge starts to cure, thereby slowing down the spreading of the second packaging adhesive 4 in all directions from the center. Thus, the speed at which the second packaging adhesive 4 spreads in all directions from the center is controlled by means of the thermally conductive layer 2 exhibiting different conductivities, thereby enabling a flawless contact between the second packaging adhesive and the incompletely cured first packaging adhesive, ensuring the moisture and oxygen barrier performance of the first packaging adhesive and prolonging the lifetime of the OLED device and the OLED display panel.

In an embodiment of the disclosure, the thermally conductive region at the edge of the thermally conductive layer 2 is made of a material having a high conductivity, including but not limited to a metal, a metal oxide, an inorganic/organic having a high conductivity, or a thermally conductive polymer. The thermally conductive region at the center of the thermally conductive layer 2 is made of a material having a low conductivity, including but not limited to an inorganic having a low conductivity.

In another embodiment of the disclosure, the thermally conductive region at the edge of the thermally conductive layer 2 and the thermally conductive region at the center of the thermally conductive layer 2 are made of the same basic material. In order for the thermally conductive regions at the edge and the center to exhibit different conductivities, the thermally conductive region at the edge is doped with a thermally conductive material 8 having a high conductivity, such as nano particles having high conductivity (e.g. nanotubes) or a metal, etc., as illustrated in FIG. 2. The nano particles can absorb UV light and convert it into thermal energy, thereby increasing the temperature at the edge of the second packaging adhesive and thus controlling the speed at which the second packaging adhesive spreads in all directions from the center. Meanwhile, the nano particles can also protect the OLED device from the UV light, thereby prolonging the lifetime of the OLED device and the OLED display panel.

In another embodiment of the disclosure, the thermally conductive region at the edge of the thermally conductive layer 2 and the thermally conductive region at the center of the thermally conductive layer 2 are made of the same basic material and are both doped with a thermally conductive material 8. In order for the thermally conductive regions at the edge and the center to exhibit different conductivities, the thermally conductive material 8 with which the thermally conductive region at the edge is doped has a higher concentration than the thermally conductive material with which the thermally conductive region at the center is doped. That is, the thermally conductive material 8 with which the thermally conductive region at the edge is doped has a higher concentration than the thermally conductive material with which the thermally conductive region at the center is doped, as illustrated in FIG. 3. In an alternative embodiment of the disclosure, the thermally conductive region at the edge of the thermally conductive layer 2 and the thermally conductive region at the center of the thermally conductive layer 2 are made of the same basic material, wherein the thermally conductive region at the center is doped with a thermally insulting material.

In a further embodiment of the disclosure, the thermally conductive region at the edge of the thermally conductive layer 2 and the thermally conductive region at the center of the thermally conductive layer 2 are made of the same basic material, wherein the thermally insulating material with which the thermally conductive region at the center is doped has a higher concentration than the thermally insulating material with which the thermally conductive region at the edge is doped.

The basic material may be selected from a metal, a metal oxide, an inorganic/organic having a high conductivity, or a thermally conductive polymer.

In the OLED display panel processing technology, the first substrate 1 is often called a packaging substrate and the second substrate 2 is called a device substrate.

The first packaging adhesive 3 is a dam (such as a UV curable dam or a heat curable dam), and the second packaging adhesive 4 is a filler.

The material of the first packaging adhesive 3 includes a liquid adhesive having a high viscosity and a high impermeability, and the material of the second packaging adhesive 4 includes a hydrophobic liquid adhesive having a low viscosity and a high fluidity. This is because, when the second packaging adhesive 4 fills the sealed space enclosed by the first substrate 1, the second substrate 2 and the first packaging adhesive 3, it shall have a certain fluidity so that it can finally fill up the sealed space. In an embodiment of the disclosure, the active ingredient of the material of the first packaging adhesive 3 includes epoxy resin. The second packaging adhesive 4 may contain the same ingredient as the first packaging adhesive 3, but in a different percentage. That is, the percentage of the active ingredient in the material of the second packaging adhesive 4 is lower than the percentage of the active ingredient in the material of the first packaging adhesive 3, so that the second packaging adhesive 4 has a certain fluidity.

As a preferable embodiment, at normal temperatures and pressures, the first packaging adhesive 3 has a permeability of 10-20 g/m²·d, and the second packaging adhesive 4 has a permeability of 5-10 g/m²·d.

In addition, the disclosure by no means limits the specific shape of the first packaging adhesive 3, but only requires that the first packaging adhesive 3 can be connected between the first substrate 1 and the second substrate 6 and enclose a sealed space with the first substrate 1 and the second substrate 6 and the sealed space can completely accommodate the OLED device arranged on the second substrate 6. Of course, because the OLED display panel is typically rectangular, the first packaging adhesive 3 as a whole is in typically a frame which is also rectangular.

Specifically, the OLED device may be a top-emitting OLED or a bottom-emitting OLED. However, the disclosure by no means limits the specific type of the OLED device.

In an embodiment of the disclosure, the OLED display panel further comprises a passivation layer 5 covering the OLED device and connected to the second substrate 6 in a sealed manner. The passivation layer 5 further protects the OLED device from substances such as moisture or oxygen, etc. The material of the passivation layer 5 may be silicon nitride, silicon oxide or the like. As a preferable embodiment, the passivation layer 5 has a permeability of 10⁻⁴ g/m²·d at normal temperatures and pressures.

According to the above technical solutions, the first packaging adhesive 3 encloses a sealed space with the first substrate 1 and the second substrate 6, the second packaging adhesive 4 fills the sealed space enclosed by the first substrate 1, the second substrate 6 and the first packaging adhesive 3, and the thermally conductive layer 2 in contact with the second packaging layer 2 has a higher conductivity at the edge than at the center. As such, a temperature difference is created between different positions on the second packaging adhesive and thus the speed at which the second packaging adhesive spreads in all directions from the center is controlled, thereby enabling a flawless contact between the second packaging adhesive and the incompletely cured first packaging adhesive and preventing the second packaging adhesive from causing damage to the first packaging adhesive. Additionally, the first packaging adhesive, the second package adhesive and the passivation layer can all block moisture and oxygen. Meanwhile, the passivation layer can also prevent the second packaging adhesive from directly contacting the OLED device and thus affecting the performance characteristics of the OLED device. Therefore, the technical solutions of the disclosure can not only ensure moisture and oxygen barrier performance of the first packaging adhesive but also fully insulate the functional layers of the OLED device from substances in the atmosphere such as moisture, oxygen, etc., thereby significantly prolonging the lifetime of the OLED device and the OLED display panel.

According to another aspect of the disclosure, there is provided an OLED display apparatus, which comprises the OLED display panel according to any of the above-described embodiments.

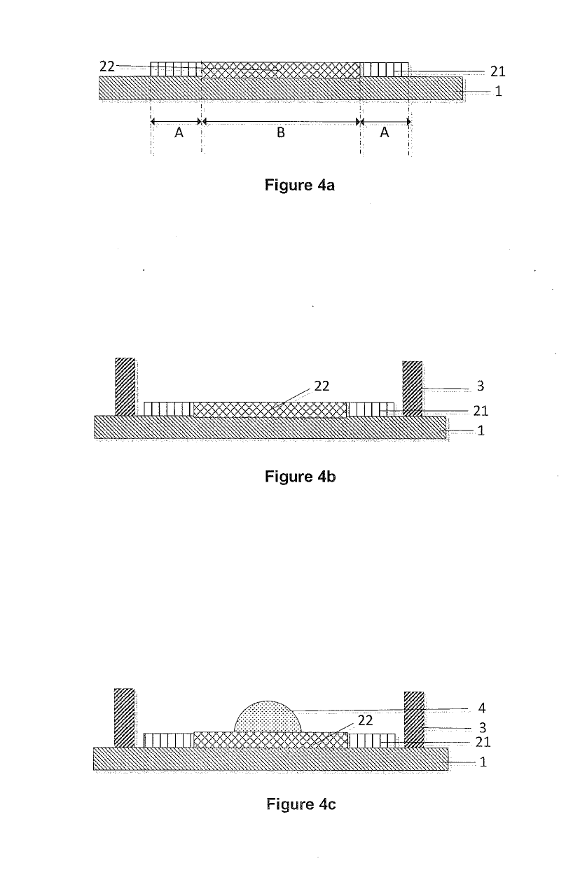

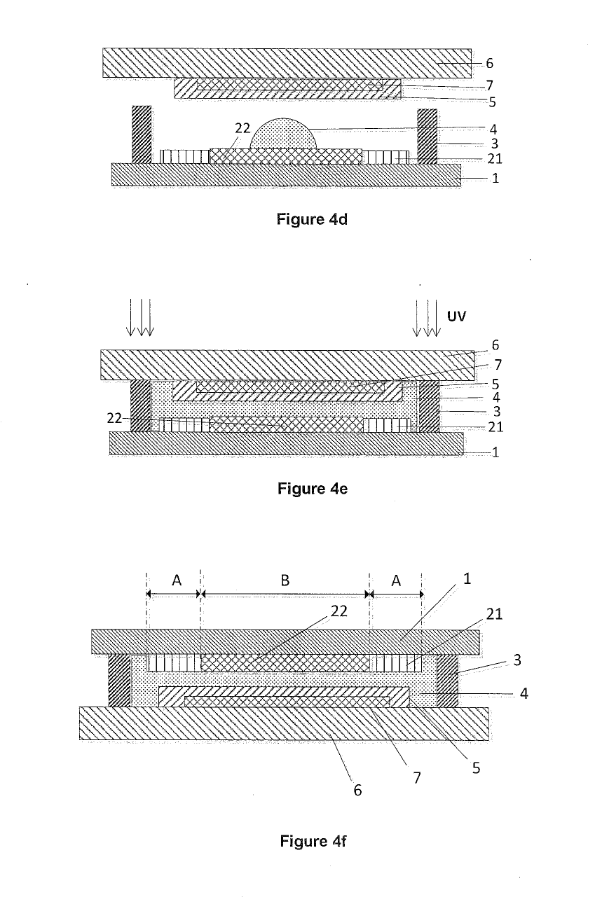

According to a further aspect of the disclosure, there is provided a method for packaging an OLED device. As shown in FIG. 4, the method for packaging the OLED device comprises the following steps.

At step 1, a thermally conductive layer 2, which includes at least two regions having different conductivities, is formed on a surface of a first substrate 1 or a second substrate 2. At least an edge region of the thermally conductive layer 2 has a higher conductivity than a central region of the thermally conductive layer 2, as illustrated in FIG. 4a.

Specifically, at least two thermally conductive regions are formed on the surface of the first substrate 1 or the second substrate 6 from the edge to the center of the first substrate 1 or the second substrate 6, and conductivities of the thermally conductive regions decrease monotonically from the edge to the center.

In an embodiment of the disclosure, the thermally conductive layer 2 is formed on the surface of the first substrate 1. Preferably, a first thermally conductive region 21 is formed at the edge of the first substrate 1 and a second thermally conductive region 22 is formed at the center of the first substrate 1, wherein the first thermally conductive region 21 has a higher conductivity than the second thermally conductive region 22.

It can be envisaged that there are many other positions and formations of the thermally conductive regions in the thermally conductive layer 2. For example, the thermally conductive regions may be arranged in strips, and the thermally conductive region at the edge of the thermally conductive layer 2 has higher conductivities than the thermally conductive region at the center of the thermally conductive layer 2. As another example, the thermally conductive layer 2 may include multiple thermally conductive regions, each of which has a regular or irregular shape. The thermally conductive regions are arranged according to a certain pattern to constitute the thermally conductive layer 2. Each thermally conductive region at the edge of the thermally conductive layer 2 has a higher conductivity than the thermally conductive regions at the center of the thermally conducive layer 2. The conductivities of the thermally conductive regions at the edge may be the same, different or locally the same. The conductivities of the thermally conductive regions at the center may be the same, different, or locally the same.

The thermally conductive layer 2 typically has a shape of rectangle, such as an oblong or a square.

The disclosure by no means limit the specific positions and formation of the thermally conductive regions in the thermally conductive layer 2 but only requires that the thermally conductive layer 2 includes at least two thermally conductive regions and conductivities of the at least two thermally conductive regions decrease monotonically from the edge to the center of thermally conductive layer 2. Also, the disclosure by no means limits the shape of the thermally conductive layer 2, and any suitable shape that can be formed within the space enclosed by the first packaging adhesive 3 falls within the protection scope of the disclosure.

As described above, the thermally conductive layer 2 includes at least two regions having different conductivities. In the following, description will be given by taking an example where the thermally conductive layer 2 includes two regions having different conductivities. However, those skilled in the art shall appreciate that details for the case where the number of regions having different conductivities is more than two can be deduced from the case where there are two regions having different conductivities. No repetition will be made in the following. As for the case where the thermally conductive layer 2 includes two regions having different conductivities which are respectively located at the center and the edge and the conductivity of the first thermally conductive region 21 at the edge is higher than the conductivity of the second thermally conductive region 22 at the center, such a design is made for enabling the thermally conductive layer 2 to exhibit different conductivities when packaging a prepared panel, so that there is a temporal temperature difference between different thermally conductive regions. That is, the thermally conductive layer 2 has a higher temperature at the edge than at the center, and thus the second packaging adhesive 4 in contact with the surface of the thermally conductive layer 2 also exhibits different temperatures at positions corresponding to those on the thermally conductive layer 2. Therefore, when the second packaging adhesive 4 quickly spreads from the center to the edge and reaches the edge where the temperature is high, the second packaging adhesive in contact with the thermally conductive layer 2 will have a higher curing rate at the edge than at the center. The second packaging adhesive 4 at the edge starts to cure, thereby slowing down the spreading of the second packaging adhesive 4 in all directions from the center. Thus, the speed at which the second packaging adhesive 4 spreads in all directions from the center is controlled by means of the thermally conductive layer 2 exhibiting different conductivities, thereby enabling a flawless contact between the second packaging adhesive and the incompletely cured first packaging adhesive, ensuring the moisture and oxygen barrier performance of the first packaging adhesive and prolonging the lifetime of the OLED device and the OLED display panel.

In an example, at step 1, a first thermally conductive layer having a high conductivity is firstly formed at the edge of the first substrate 1 (illustrated as region A in FIG. 4a) by using processes such as sputtering or evaporation, etc. The material of the first thermally conductive layer includes but is not limited to a metal, a metal oxide, an inorganic/organic having a high conductivity, a thermally conductive polymer or the like. Then, a second thermally conductive layer having a low conductivity is formed at the center of the first substrate 1 (illustrated as region B in FIG. 4a) by using processes such as coating and printing, etc. The material of the second thermally conductive layer includes but is limited to an inorganic having a low conductivity or the like. As such, it is achieved that the conductivity of the thermally conductive region at the edge of the first substrate 1 is higher than the conductivity of the thermally conductive region 22 at the center of the first substrate 1, as illustrated in FIG. 4a.

In another example, at step 1, a first thermally conductive layer having a high conductivity is firstly formed at the surface of the first substrate 1 by using processes such as sputtering or evaporation, etc. The material of the first thermally conductive layer includes but is not limited to a metal, a metal oxide, an inorganic/organic having a high conductivity, a thermally conductive polymer or the like. Then, a second thermally conductive layer having a low conductivity is formed at the center of the first thermally conductive layer by using processes such as coating and printing, etc. The material of the second thermally conductive layer includes but is not limited to an inorganic having a low conductivity or the like. As such, it is achieved that the conductivity of the thermally conductive region at the edge of the first substrate 1 is higher than the conductivity of the thermally conductive region at the center of the first substrate 1.

In another embodiment, at step 1, a first thermally conductive layer is firstly formed at the surface of the first substrate 1 by using processes such as sputtering or evaporation, etc. Then, the first thermally conductive layer at the edge of the first substrate 1 is doped with a thermally conductive material 8 having a high conductivity, such as nano particles having high conductivity (e.g. nanotubes) or a metal, etc. As such, it can also be achieved that the conductivity of the thermally conductive region at the edge is higher than the conductivity of the thermally conductive region at the center. The nano particles can absorb UV light and convert it into thermal energy, thereby increasing the temperature of the second packaging adhesive at the edge and thus controlling the speed at which the second packaging adhesive 4 spreads in all directions from the center. Meanwhile, the nano particles can also protect the OLED device from the UV light, thereby prolonging the lifetime of the OLED device and the OLED display panel.

In another example, at step 1, a first thermally conductive layer is firstly formed at the surface of the first substrate 1 by using processes such as sputtering or evaporation, etc. Then, the first thermally conductive layer is doped with a thermally conductive material 8 having a high conductivity. The the thermally conductive material 8 with which the thermally conductive region at the edge is doped has a higher concentration than the thermally conductive material 8 with which the thermally conductive region at the center is doped.

In another example, at step 1, a first thermally conductive layer is firstly formed at the surface of the first substrate 1 by using processes such as sputtering or evaporation, etc. Then, the first thermally conductive layer at the center of the first substrate 1 is doped with a thermally insulting material having a low conductivity.

In a further example, at step 1, a first thermally conductive layer is firstly formed at the surface of the first substrate 1 by using processes such as sputtering or evaporation, etc. Then, the first thermally conductive layer is doped with a thermally insulting material having a low conductivity. The thermally insulating material with which the thermally conductive region at the center is doped has a higher concentration than the thermally insulating material with which the thermally conductive region at the edge is doped. As such, it can also be achieved that the conductivity of the thermally conductive region at the edge is higher than the conductivity of the thermally conductive region at the center.

In addition, the disclosure by no means limits the specific position where the thermally conductive layer is formed, but only requires that the thermally conductive layer 2 is within the space enclosed by the first packaging adhesive and all or part of its surface is in contact with the second packaging adhesive 4.

At step 2, the first packaging adhesive 3 is formed on a peripheral edge of the first substrate 1 or the second substrate 6 so that the first packaging adhesive 3 encloses a sealed space with the first substrate 1 and the second substrate 6. The thermally conductive layer 2 is arranged within the space enclosed by the first packaging adhesive 3, as illustrated in FIG. 4b.

The first packaging adhesive 3 may be formed on the first substrate or the second substrate. In the example of step 2, the first packaging adhesive 3 is formed on the surface of the first substrate 1. More preferably, the first packaging adhesive 3 is formed on the peripheral edge of the first substrate 1.

The disclosure by no means limits the specific position where the first packaging adhesive 3 is formed, but only requires that the first packaging adhesive 3 is between the first substrate 1 and the second substrate 6, encloses a sealed space with the first substrate 1 and the second substrate 6, and surrounds the thermally conductive layer 2.

At step 3, the second packaging adhesive 4 is formed on the first substrate 1 or the second substrate 6, as illustrated in FIG. 4c.

Forming the second packaging adhesive 4 on the first substrate) or the second substrate 6 refers to: forming the second packaging adhesive 4 on the first substrate 1 or the second substrate 6 where the thermally conductive layer 2 is formed, in case the thermally conductive layer 2 is formed on the first substrate 1; forming the second packaging adhesive 4 on the second substrate 6 or the first substrate 1 where the thermally conductive layer 2 is formed, in case the thermally conductive layer 2 is formed on the second substrate 6. The disclosure by no means limits the position where the second packaging adhesive 4 is formed, but only requires that the second packaging adhesive 4 is within the space enclosed by the first packaging adhesive 3, the first substrate 1 and the second substrate 6.

The first packaging adhesive 3 is a dam (such as a UV curable dam or a heat curable dam), and the second packaging adhesive 4 is a filler.

The material of the first packaging adhesive 3 includes a liquid adhesive having a high viscosity and a high impermeability, and the material of the second packaging adhesive 4 includes a hydrophobic liquid adhesive having a low viscosity and a high fluidity. This is because, when the second packaging adhesive 4 fills the sealed space enclosed by the first substrate 1, the second substrate 2 and the first packaging adhesive 3, it shall have a certain fluidity so that it can finally fill up the sealed space. At step 3, the active ingredient of the material of the first packaging adhesive 3 includes epoxy resin. The second packaging adhesive 4 may contain the same ingredient as the first packaging adhesive 3, but in a different percentage. That is, the percentage of the active ingredient in the material of the second packaging adhesive 4 is lower than the percentage of the active ingredient in the material of the first packaging adhesive 3, so that the second packaging adhesive 4 has a certain fluidity.

As a preferable embodiment, at normal temperatures and pressures, the first packaging adhesive 3 has a permeability of 10-20 g/m²·d, and the second packaging adhesive 4 has a permeability of 5-10 g/m²·d.

In addition, the disclosure by no means limits the specific shape of the first packaging adhesive 3, but only requires that the first packaging adhesive 3 can be connected between the first substrate 1 and the second substrate 6 and enclose a sealed space with the first substrate 1 and the second substrate 6 and the sealed space can completely accommodate the OLED device arranged on the second substrate 6. Of course, because the OLED display panel is typically rectangular, the first packaging adhesive 3 as a whole is typically a frame which is also rectangular.

The second packaging adhesive 4 may be formed using a dispenser or the like. The disclosure by no means limits the specific manner for placing the second packaging adhesive 4. However, those skilled in the art shall appreciate that any processing manner that can effectively form the second packaging adhesive 4 without damaging the thermally conductive layer 2 falls within the protection scope of the disclosure.

It shall be noted that the disclosure by no means limits the sequence of step 1, step 2 and step 3 and the above sequence is optional. It can be understood that: in case the second packaging adhesive 4 is not prepared on the thermally conducive layer, the sequence of step 1, step 2 and step 3 can be changed arbitrarily; in case the second packaging adhesive 4 is prepared on the thermally conductive layer, it suffices that step 3 is performed after step 1.

At step 4, the second substrate 6 where the OLED device is formed is connected with the first substrate 1 via the first packaging adhesive 3, wherein the first packaging adhesive 3 encloses the sealed space with the first substrate 1 and the second substrate 6, as illustrated in FIG. 4d.

Specifically, the OLED device may be a top-emitting OLED or a bottom-emitting OLED. However, the disclosure by no means limits the specific type of the OLED device.

In an example, before step 4, the packaging method further comprises: forming, on the OLED device, a passivation layer 5 connected to the second substrate 6 in a sealed manner, as illustrated in FIG. 4d. The passivation layer 5 further protects the OLED device from substances such as moisture or oxygen, etc. The material of the passivation layer 5 may be silicon nitride, silicon oxide or the like. As a preferable embodiment, the passivation layer 5 has a permeability of 10⁻⁴ g/m²·d at normal temperatures and pressures.

At step 5, the first packaging adhesive 3 is cured, as illustrated in FIG. 4e.

At this step, the type of the curing process is selected according to the type of the first packaging adhesive 3. For example, if the first packaging adhesive 3 is a UV curable adhesive, then the UV curing process is selected, as illustrated in FIG. 4e. If the first packaging adhesive 3 is a heat curable adhesive, then the heat curing process is selected. At this step, the second packaging adhesive has started to spread but does not fill up the sealed space.

At step 6, the second packaging adhesive 4 is cured, as illustrated in FIG. 4f. At this point, the packaging of the OLED device is completed,

In an example, the curing of the second packaging adhesive 4 by using the heat curing process at step 6 is performed by transferring a mechanism which has cured the first packaging adhesive 3 to a hot plate for heat-curing the second packaging adhesive 4.

Since the thermally conductive layer 2 includes at least two regions having different conductivities and the conductivity of the thermally conductive region at the edge is higher than the conductivity of the thermally conductive region at the center according to the disclosure, there will be a temporal temperature difference between different thermally conductive regions on the thermally conductive layer 2, when the first packaging adhesive 3 is cured. That is, the thermally conductive layer 2 has a higher temperature at its edge than at its center. Therefore, the second packaging adhesive 4 in contact with the surface of the thermally conductive layer 2 also exhibits different temperatures at positions corresponding to those on the thermally conductive layer 2, so that the second packaging adhesive 4 quickly spreads from the center to the edge. When the second packaging adhesive 4 reaches the edge where the temperature is high, the curing rate of the second packaging adhesive at the edge will be higher than the curing rate of the second packaging adhesive at the center. The second packaging adhesive 4 at the edge starts to cure, thereby slowing down the spreading of the second packaging adhesive 4 in all directions from the center. Accordingly, when the first packaging adhesive 3 is cured, the second packaging adhesive 4 spreads in all directions from the center but does not fill up the sealed space enclosed by the first substrate 1, the second substrate 6 and the first packaging adhesive 3. After the curing of the second packaging adhesive 4 is completed, the second packaging adhesive 4 has filled up the sealed space enclosed by the first substrate 1, the second substrate 6 and the first packaging adhesive 3. At this point, the packaging of the OLED device is completed.

According to the above technical solutions, the first packaging adhesive 3 encloses a sealed space with the first substrate 1 and the second substrate 6, the second packaging adhesive 4 fills the sealed space enclosed by the first substrate 1, the second substrate 6 and the first packaging adhesive 3, and the thermally conductive layer 2 in contact with the second packaging adhesive 4 has a higher conductivity at the edge than at the center. As such, a temperature difference is created between different positions on the second packaging adhesive and thus the speed at which the second packaging adhesive spreads in all directions from the center is controlled, thereby enabling a flawless contact between the second packaging adhesive and the incompletely cured first packaging adhesive and preventing the second packaging adhesive from causing damage to the first packaging adhesive. Additionally, the first packaging adhesive, the second package adhesive and the passivation layer can all block moisture and oxygen. Meanwhile, the passivation layer can also prevent the second packaging adhesive from directly contacting the OLED device and thus affecting the performance characteristics of the OLED device. Therefore, the technical solutions of the disclosure can not only ensure moisture and oxygen barrier performance of the first packaging adhesive but also fully insulate the functional layers of the OLED device from substances in the atmosphere such as moisture, oxygen, etc., thereby significantly prolonging the lifetime of the OLED device and the OLED display panel.

The above detailed embodiments describe the object, technical solutions and advantages of the disclosure in further detail. It shall be appreciated that the above contents are just detailed embodiments of the disclosure and are not intended to limit the disclosure. Any alterations, equivalent replacements, improvements, etc. made within the spirit and scope of the disclosure shall be encompassed by the protection scope of the disclosure.

1. An OLED display panel, comprising:
a first substrate;
a second substrate arranged opposite to the first substrate; and
a thermally conductive layer, a first packaging adhesive, a second packaging adhesive and an OLED device between the first substrate and the second substrate, wherein
the first packaging adhesive is arranged between the first substrate and the second substrate and encloses a sealed space with the first substrate and the second substrate,
the thermally conductive layer is formed within the space enclosed by the first packaging adhesive and includes at least two regions having different conductivities, wherein at least an edge region of the thermally conductive layer has a higher conductivity than a central region of the thermally conductive layer,
the second packaging adhesive fills the space enclosed by the first substrate, the second substrate and the first packaging adhesive, and is in contact with a surface of the thermally conductive layer.

2. The OLED display panel according to claim 1, wherein the thermally conductive layer includes at least two thermally conductive regions from its edge to its center, and conductivities of the thermally conductive regions decrease monotonically from the edge to the center.

3. The OLED display panel according to claim 2, wherein a material of a thermally conductive region at the edge of the thermally conductive layer has a higher conductivity than a material of a thermally conductive region at the center of the thermally conducive layer, or
the thermally conductive region at the edge of the thermally conductive layer and the thermally conductive region at the center of the thermally conductive layer are made of the same basic material, wherein a material layer having a lower conductivity is formed at the thermally conductive region at the center, or
the thermally conductive region at the edge of the thermally conductive layer and the thermally conductive region at the center of the thermally conductive layer are made of the same basic material, wherein the thermally conductive region at the edge is doped with a thermally conductive material, or
the thermally conductive region at the edge of the thermally conductive layer and the thermally conductive region at the center of the thermally conductive layer are made of the same basic material and are both doped with a thermally conductive material, wherein the thermally conductive material with which the thermally conductive region at the edge is doped has a higher concentration than the thermally conductive material with which the thermally conductive region at the center is doped, or
the thermally conductive region at the edge of the thermally conductive layer and the thermally conductive region at the center of the thermally conductive layer are made of the same basic material, wherein the thermally conductive region at the center is doped with a thermally insulting material, or
the thermally conductive region at the edge of the thermally conductive layer and the thermally conductive region at the center of the thermally conductive layer are made of the same basic material, wherein the thermally insulating material with which the thermally conductive region at the center is doped has a higher concentration than the thermally insulating material with which the thermally conductive region at the edge is doped.

4. The OLED display panel according to claim 3, wherein the material of the thermally conductive region at the edge is selected from a metal, a metal oxide, an inorganic/organic having a high conductivity, or a thermally conductive polymer, and the material of the thermally conductive region at the center is an inorganic having a low conductivity; or the basic material is selected from a metal, a metal oxide, an inorganic/organic having a high conductivity, or a thermally conductive polymer, and the material having a lower conductivity is an inorganic having a low conductivity; or the basic material is selected from a metal, a metal oxide, an inorganic/organic having a high conductivity, or a thermally conductive polymer, and the thermally conductive material is carbon nanotubes or a metal.

5. The OLED display panel according to claim 1, wherein the thermally conductive layer is rectangular.

6. The OLED display panel according to claim 1, further comprising: a passivation layer covering the OLED device and connected to the second substrate in a sealed manner.

7. An OLED display apparatus, comprising an OLED display panel according to claim 1.

8. A method for packaging an OLED device, the method comprising:
forming a thermally conductive layer, which includes at least two regions having different conductivities, on a surface of a first substrate or a second substrate, wherein at least an edge region of the thermally conductive layer has a higher conductivity than a central region of the thermally conductive layer;
forming a first packaging adhesive on a peripheral edge of the first substrate or the second substrate so that the first packaging adhesive encloses a sealed space with the first substrate and the second substrate, the thermally conductive layer being arranged within the space enclosed by the first packaging adhesive;
forming a second packaging adhesive on the first substrate or the second substrate;
connecting the second substrate where the OLED device is formed and the first substrate via the first packaging adhesive, wherein the first packaging adhesive encloses the sealed space with the first substrate and the second substrate;
curing the first packaging adhesive and the second packaging adhesive respectively, so that the second packaging adhesive fills up the sealed space.

9. The packaging method according to claim 8, wherein at least two thermally conductive regions are formed on the surface of the first substrate or the second substrate from an edge to a center of the first substrate or the second substrate, and conductivities of the thermally conductive regions decrease monotonically from the edge to the center.

10. The packaging method according to claim 9, wherein the at least two thermally conductive regions are formed on the surface of the first substrate or the second substrate from the edge to the center of the first substrate or the second substrate by:
forming a first thermally conductive layer at the edge of the first substrate or the second substrate and forming a second thermally conductive layer at the center of the first substrate or the second substrate, wherein a material of the first thermally conductive layer has a higher conductivity than a material of the second thermally conductive layer, or
forming a first thermally conductive layer on the surface of the first substrate or the second substrate and forming a second thermally conductive layer at the center of the first thermally conductive layer, wherein a material of the first thermally conductive layer has a higher conductivity than a material of the second thermally conductive layer, or
forming a first thermally conductive layer on the surface of the first substrate or the second substrate and doping the first thermally conductive layer at its edge with a thermally conductive material;
forming a first thermally conductive layer on the surface of the first substrate or the second substrate and doping the first thermally conductive layer with a thermally conductive material, wherein the thermally conductive material in a thermally conductive region at the edge has a higher concentration than in a thermally conductive region at the center, or
forming a first thermally conductive layer on the surface of the first substrate or the second substrate and doping the first thermally conductive layer at its center with a thermally insulating material, or
forming a first thermally conductive layer on the surface of the first substrate or the second substrate and doping the first thermally conductive layer with a thermally conductive material, wherein the thermally insulating material in a thermally conductive region at the center has a higher concentration than in a thermally conductive region at the edge.

11. The packaging method according to claim 8, wherein a material of the first packaging adhesive includes a liquid adhesive having a high viscosity and a high impermeability, and a material of the second packaging adhesive includes a hydrophobic liquid adhesive having a low viscosity and a high fluidity.

12. The packaging method according to claim 8, wherein an active ingredient of the materials of both the first packaging adhesive and the second packaging adhesive includes epoxy resin, and the epoxy resin accounts for a lower percentage in the material of the second packaging adhesive than in the material of the first packaging adhesive.

13. The packaging method according to claim 8, further comprising: forming, on the OLED device, a passivation layer connected to the second substrate (6) in a sealed manner, before connecting the second substrate where the OLED device is formed and the first substrate via the first packaging adhesive.

14. The packaging method according to claim 9, wherein a material of the first packaging adhesive includes a liquid adhesive having a high viscosity and a high impermeability, and a material of the second packaging adhesive includes a hydrophobic liquid adhesive having a low viscosity and a high fluidity.

15. The packaging method according to claim 10, wherein a material of the first packaging adhesive includes a liquid adhesive having a high viscosity and a high impermeability, and a material of the second packaging adhesive includes a hydrophobic liquid adhesive having a low viscosity and a high fluidity.

16. The packaging method according to claim 9, wherein an active ingredient of the materials of both the first packaging adhesive and the second packaging adhesive includes epoxy resin, and the epoxy resin accounts for a lower percentage in the material of the second packaging adhesive than in the material of the first packaging adhesive.

17. The packaging method according to claim 10, wherein an active ingredient of the materials of both the first packaging adhesive and the second packaging adhesive includes epoxy resin, and the epoxy resin accounts for a lower percentage in the material of the second packaging adhesive than in the material of the first packaging adhesive.
